(19) United States
(12) Patent Application Publication
(10) Pub. No.: US 2004/0229453 A1
(43) Pub. Date: Nov. 18, 2004

(54) Methods of pore sealing and metal encapsulation in porous low k interconnect

(75) Inventor: Dung-Ching Perng, Fremont, CA (US)

Correspondence Address: CHARLES E. RUNYAN, SQUIRE, SANDERS & DEMPSEY LLP, ONE MARITIME PLAZA,, SUITE 300, SAN FRANCISCO,, CA, 94111, US

(73) Assignee: JSR Micro, Inc., Sunnyvale, CA (US)

(21) Appl. No.: 10/439,415

(22) Filed: May 15, 2003

(51) Int. Cl. H01L 23/48

(52) U.S. Cl. 438/622

(57) ABSTRACT

One method includes porous low k pore sealing that uses a combination of materials that bond and expand, thereby covering any pore or irregularities in the surface of an insulator adjacent to a conductor. The materials form a substantially impermeable barrier between the conductor and insulator that prevents leakage of the conductor into the insulator. Another method encapsulates the conductor on all exposed surfaces with an impermeable barrier before placement of an insulator, thereby preventing both anode extrusion and diffusion via pores in the insulator.

### TECHNICAL FIELD

This invention relates generally to integrated circuits, and more particularly, but not exclusively, provides integrated circuits and methods that prevent a conductor from leaking into an insulator region of an integrated circuit.

### BACKGROUND

An integrated circuit (IC) is a group of interconnected circuit elements formed on or within a continuous substrate. ICs are used in microprocessors, electronic equipment, automobiles, mobile telephones, and other devices. ICs, such as the IC 100, a segment of which is shown in cross section in FIG. 1, includes a conductor 145, made of copper or other conductor, surrounded by a porous low dielectric constant (k) material 140 (e.g., an insulator), made of JSR LKD or other low k material. Between the conductor 145 and low k material 140 a barrier 160a of Ta and/or TaN metal or barrier material is disposed. The IC 100 also includes a bottom barrier layer 130 of SiCN or other material (e.g., SiC, SiN, etc.) disposed on an oxide layer 120, which is disposed on a substrate layer 110. Further, the low k material 140 and the conductor 145 can be capped with a cap 150 made of, for example, SiC, SiCN, SiN or other dielectric.

Reliability issues arise during operation of conventional ICs, such as the IC 100. A major reliability issue is that the conductor 145 diffuses into the porous low k material 140 even though a barrier 160a is in place between the conductor 145 and the low k material 140 to prevent diffusion. Diffusion of the conductor 145 into the low k material 140, as indicated by the arrows 180, causes reliability problems such as high leakage current between metals and lessens the conductivity of the conductor 145.

The diffusion of the conductor 145 into the low k material 140 is caused by the porous nature of the low k material 140, which encourages diffusion/migration of the conductor 145. In addition, the barrier 160a may be non-continuous with the sidewalls of the low k material 140, thereby providing opportunities for the conductor 145 to diffuse into the insulator 140. For example, the sidewalls of the low k material 140 are generally uneven and rough, thereby preventing the barrier 160a from forming a complete continuous seal against diffusion of the conductor 145 with limited barrier deposition. Additional barrier deposition to form a continuous seal leaves limited volume for the conductor, which can cause excessive current density and higher resistance.

Another reliability issue of conventional ICs is anode extrusion of the conductor 145 from underneath the cap 150 onto the low k material 140. The anode extrusion lowers the conductivity of the conductor 145 and is caused by adhesion weakness between the low k material 140 and the cap 150.

Accordingly, new ICs and IC manufacturing methods are needed that substantially overcome the reliability issues mentioned above.

### SUMMARY

In one embodiment, an integrated circuit comprises a substrate; a dielectric layer; a conductor layer; and a substantially impermeable barrier. The dielectric layer is disposed on the substrate and has a trench disposed therein. The conductor disposed within the trench. The substantially impermeable barrier, which includes at least two different materials bonded together, is located between the conductor and the dielectric layer.

In an embodiment of the invention, the integrated circuit can be formed by forming a trench in a layer of dielectric material on a substrate; depositing a first material into the trench; depositing a second material into the trench; and applying energy to the first and second materials to cause them to form a barrier along at least a portion of the sides and bottom of the trench.

In another embodiment of the invention, an integrated circuit comprises a conductor, a substantially impermeable barrier and an insulator. The conductor is disposed on a substrate. The substantially impermeable barrier encapsulates at least a top surface and side surfaces of the conductor and the insulator is adjacent to at least a portion of the barrier.

In an embodiment of the invention, the integrated circuit is formed by forming a conductor island on a substrate; encapsulating at least the side surfaces and the top surface of the conductor with a barrier material; and optionally depositing an insulator on the substrate adjacent to at least a portion of the barrier material.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a cross section illustrating a conventional IC;

FIG. 2 includes cross sections illustrating an IC undergoing barrier deposition according to an embodiment of the invention;

FIG. 3 is a flowchart illustrating a method of barrier deposition according to an embodiment of the invention;

FIG. 4 is a cross section illustrating an initial stage of forming an IC according to an embodiment of the invention;

FIG. 5 is a partial cross section illustrating a second stage of forming an IC;

FIG. 6 is a partial cross section illustrating a third stage of forming an IC;

FIG. 7 is a partial cross section illustrating a fourth stage of forming an IC;

FIG. 8 is a partial cross section illustrating a fifth stage of forming an IC;

FIG. 9 is a partial cross, section illustrating a sixth stage of forming an IC;

FIG. 10 is a partial cross section illustrating a seventh stage of forming an IC;

FIG. 11 is a partial cross, section illustrating an eighth stage of forming an IC;

FIG. 12 is a partial cross section illustrating a first stage of forming a dual damascene IC;

FIG. 13 is a partial cross section illustrating a second stage of forming a dual damascene IC;

FIG. 14 is a partial cross section illustrating a third stage of forming a dual damascene IC;

FIG. 15 is a partial cross section illustrating a fourth stage of forming a dual damascene IC;

FIG. 16 is a partial cross section illustrating a fifth stage of forming a dual damascene IC;

FIG. 17 is a partial cross section illustrating a sixth stage of forming a dual damascene IC;

FIG. 18 is a partial cross section illustrating a single damascene IC having a recessed dielectric;

FIG. 19 is a partial cross section illustrating a dual damascene IC having a recessed dielectric; and

FIG. 20 is a flowchart illustrating a method of IC formation according to an embodiment of the invention.

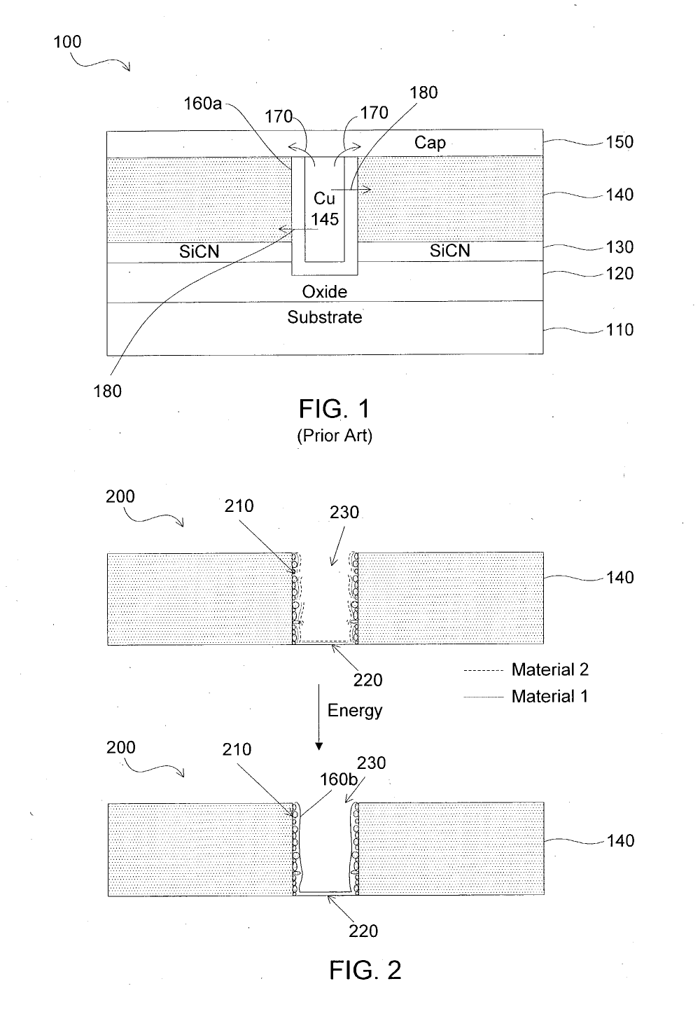

### DETAILED DESCRIPTION OF THE ILLUSTRATED EMBODIMENTS

The following description is provided to enable any person having ordinary skill in the art to make and use the invention, and is provided in the context of a particular application and its requirements. Various modifications to the embodiments will be readily apparent to those skilled in the art, and the principles defined herein may be applied to other embodiments and applications without departing from the spirit and scope of the invention. Thus, the present invention is not intended to be limited to the embodiments shown, but is to be accorded the widest scope consistent with the principles, features and teachings disclosed herein.

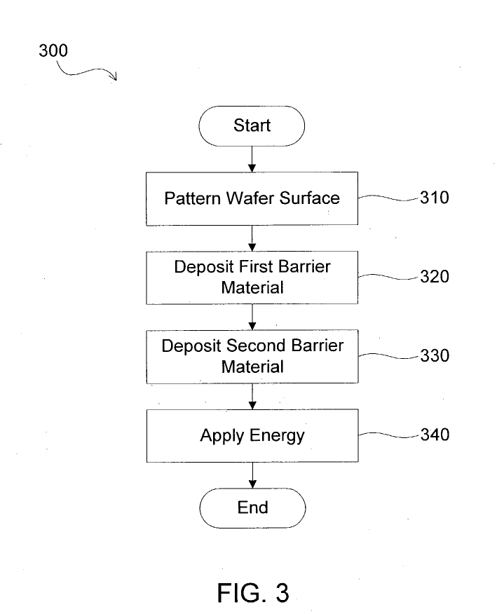

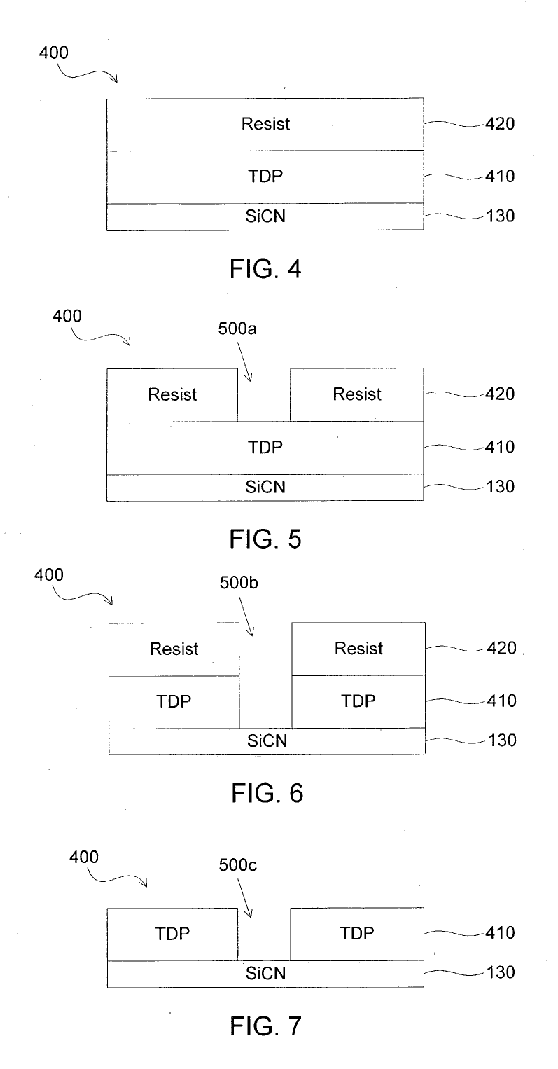

Multiple embodiments of the invention are described herein to overcome the deficiencies mentioned above. A first embodiment, as discussed below in conjunction with FIG. 2 and FIG. 3, includes porous low k pore sealing that uses a combination of materials that bond and expand, thereby covering any pore or irregularities in the surface of an insulator adjacent to a conductor. The materials form a substantially impermeable barrier between the conductor and insulator that prevents leakage of the conductor into the insulator. Additional embodiments, as discussed below in conjunctions with FIG. 4 through FIG. 20, encapsulates the conductor on all exposed surfaces (e.g., the top surface, side surfaces, and possibly a portion of the bottom surface) with a substantially impermeable barrier before placement of an insulator, thereby preventing both anode extrusion and diffusion via pores into the insulator.

FIG. 2 includes cross sections of an IC 200 under construction undergoing a barrier deposition according to an embodiment of the invention. The IC 200 includes an insulator 140 with a trench 230 formed therein for placement of a conductor. Other layers of the IC 200 are not shown. The insulator 140 can have a height and width, each about 30 nm to about 100 μm between conductors and can be made of a porous low k material, a silane based oxide, fluorine doped oxide, TEOS based oxide, or carbon doped oxide. The insulator 140 can be formed on the IC 200 via chemical vapor deposition (CVD) for about 2 minutes with the trench formed via photomasking and etching after the CVD. In another embodiment of the invention, the insulator 140 can be formed via spin on.

After the trench 230 is formed, a first material and a second material are then deposited on the sidewalls 210 and the floor 220 of the trench 230. In an embodiment of the invention, additional materials can also be deposited on the sidewalls 210 and the floor 220. The two or more materials can be deposited via physical vapor deposition (PVD) or other methods, such as CVD or atomic layer deposition (ALD). The initial deposition may not seal the discontinuities in the sidewalls 210 due to the roughness of the sidewalls 210. Accordingly, a conductor formed within the trench 230 may still diffuse into the insulator 140.

To create a better seal, energy is applied to the materials deposited. The application of energy to the IC 200 causes the two deposited materials to react or alloy to form a compound so that the grain growth or atoms locally move to seal any pores and cover any roughness in the sidewalls 210, thereby forming a complete continuous barrier 160b that substantially prevents diffusion of the conductor into the insulator 140. The barrier 160b can have a thickness of about 2 nm to about 200 nm. The application of energy can include thermal annealing, lasers, electron beams, microwave energy, UV light, etc. The deposited materials used to form the barrier 160b can include palladium (Pd) and platinum (Pt) or other materials. In an embodiment of the invention, the compound can include a silicide formation. For example, silicon (Si) can be used in addition to the Pd and Pt to form Pd₂Si between a temperature of about 200 to about 500 Celsius and PtSi between a temperature of about 300 to about 600 Celsius. The non-uniform deposited silicon and metal cause locally enhanced movement of the metal or silicon, thereby helping to seal any pores in the in the trench 230.

After the barrier 160b is formed, the IC 200 can be completed via conventional techniques, thereby forming an IC with a higher reliability than conventional ICs due to the barrier 160b that substantially prevents diffusion of a conductor in the trench 230 into the insulator 140. The conductor formed in the trench 230 can have a width of about 30 nm to about 100 μm.

FIG. 3 is a flowchart illustrating a method 300 of barrier deposition according to an embodiment of the invention. First a wafer surface is patterned (310) via conventional techniques to form a trench within an insulator. Next, a first barrier material, such as a metal or dielectric, is deposited (320) into the trench using PVD or other techniques. A second barrier material, such as a second metal or dielectric, is then deposited (330) into the trench using PVD or other techniques. In an embodiment of the invention, silicon can also be deposited into the trench for silicide formation. Examples of materials suitable for deposition (320, 330) include Pd and Pt. Energy is then applied (340) so that the two or more materials alloy or bond and expand, thereby forming a substantially impermeable barrier to prevent diffusion of a conductor into an insulator. Energy application (340) techniques can include thermal annealing, lasers, e-beams, microwaves, and/or UV lighting, etc. The method 300 then ends. The IC 200 can then be completed by forming a conductor within the trench and capping the conductor using conventional techniques, thereby forming an IC substantially more reliable than conventional ICs.

FIG. 4 is a partial cross section of the IC 400 illustrating an initial stage of forming the IC 400 according to an embodiment of the invention. The IC 400 will have a single damascene structure. In other embodiments of the invention, the IC 400 can include a dual damascene structure, non-damascene structure or any other damascene structure. In the initial stage, a thermal decomposable polymer (TDP) layer 410 is deposited (via PVD, CVD, etc.) on a bottom barrier layer 130 (i.e., a low k dielectric/insulator layer) of SiCN, SiC, etc. via PVD, CVD or other techniques. In another embodiment of the invention, a photoresist layer may be used in place of TDP layer 410. The TDP layer 410 generally has a thickness equal to the desired thickness of a conductor to be used in the IC 400. A photoresist layer 420, such as a Poly Isoprene polymer, is deposited (via PVD, CVD, spin on, etc.) on top of the TDP layer 410.

FIG. 5 is a partial cross section of the IC 400 illustrating a second stage of forming the IC 400. The second stage includes trench patterning of a trench 500a within the photoresist layer 420 e.g., via photolithography techniques. The trench 500a can have a width of about 30 nm to about 100 μm. Generally, the width of the trench 500a should be equal to the width of the conductor to be used in the IC 400. It will be appreciated by one of ordinary skill in the art that additional trenches 500a can be formed in the IC 400 if it is to have additional conductors.

FIG. 6 is a partial cross section of the IC 400 illustrating a third stage of forming the IC 400. The trench 500a is deepened into the TDP layer 410 forming a trench 500b, e.g., via etching techniques. The trench 500b preferably shares the same width of the trench 500a but extends through approximately the full depth of the TDP layer 410.

FIG. 7 is a partial cross section of the IC 400 illustrating a fourth stage of forming the IC 400. The photoresist layer 420 is removed, e.g., via ash and clean techniques, leaving only the TDP layer 410 having a trench 500c disposed within.

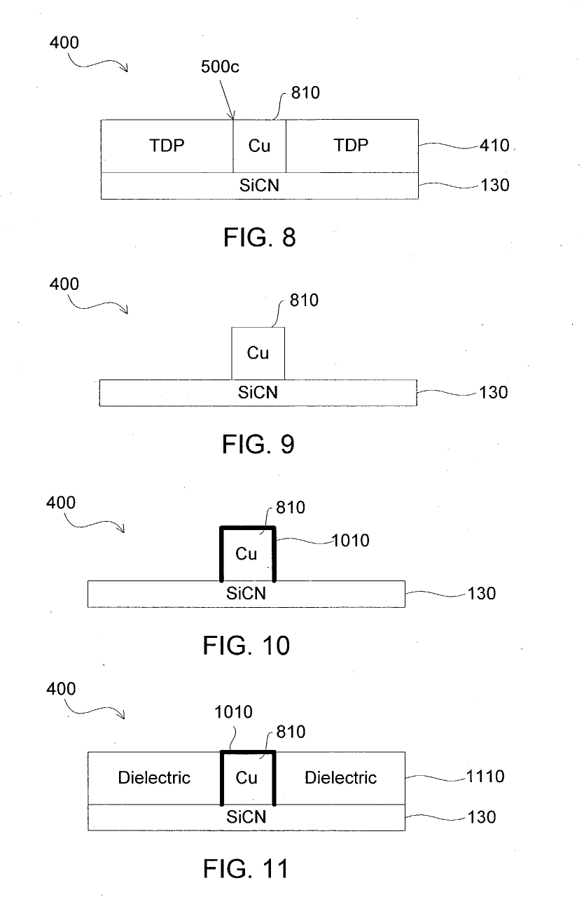

FIG. 8 is a partial cross section of the IC 400 illustrating a fifth stage of forming the IC 400. Copper or other conductor is deposited within the trench 500c, forming a conductor 810, e.g., via PVD, CVD, electrochemical plating or other techniques. In order to ensure that the height of the conductor 810 is about equal to the height of the TDP layer 410, the IC 400 preferably undergoes chemical mechanical polishing (CMP) or other technique to remove any excess conductor from the conductor 810 and remove excess metal between conductors deposited on the TDP layer 410. The conductor 810 can include copper or any other material capable of conducting electricity.

FIG. 9 is a partial cross section of the IC 400 illustrating a sixth stage of forming the IC 400. The TDP layer 410 is removed via thermal decomposition, leaving only the conductor 810 standing as an island on the bottom barrier layer 130.

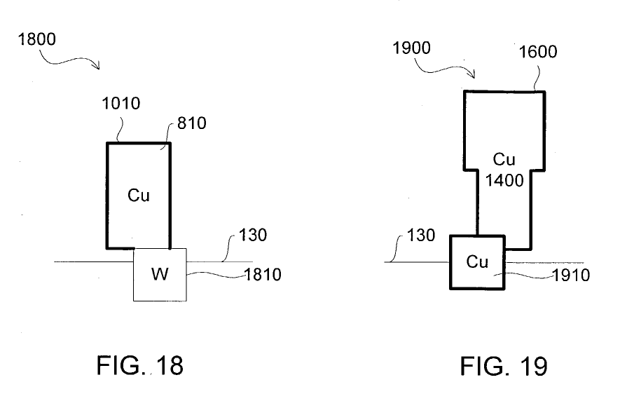

FIG. 10 is a partial cross section of the IC 400 illustrating a seventh stage of forming the IC 400. The conductor 810 is selectively coated with a barrier material to cover the top and sides (e.g., exposed surfaces) of the conductor 810 to form a barrier 1010. As will be discussed further in conjunction with FIG. 18 and 19, the barrier 1010 can also encapsulate at least a portion of the bottom of the conductor 810 in an embodiment of the invention. The barrier 1010 can be made of CoWP, CoWB, CoWB(p) or other materials and can be deposited substantially solely on the conductor 810 using electrochemical plating (ECP), electroless plating or a selective epitaxy technique. The barrier 1010 can have a thickness of about 2 nm to about 200 nm. As discussed in the 2002 International Interconnect Technology Conference (IITC) paper entitled “Electroless Deposited CoWB for Copper Diffusion Barrier Metal” by Itabashi et al., which is hereby incorporated reference, the electroless plating enables the deposition of CoWB alloy on the conductor surfaces alone by using Dimethyl Amine Borane (DMAB) as a reducing agent without the need of a palladium catalyst. The barrier 1010 decreases coupling capacity over conventional capping barriers made of SiN or SiC. Further, the barrier 1010 improves the electron migration (EM) stress migration (SM) resistance (e.g., helps prevent migration of the conductor 810).

FIG. 11 is a partial cross section of the IC 400 illustrating an eighth stage of forming the IC 400. A low k dielectric (insulator) 1110 is deposited onto the bottom barrier layer 130 surrounding the conductor 810 using spin on or CVD. CMP is used to flatten the dielectric 1110. If there are voids between the insulator 1110 and conductor 810, then the capacitance between conductors is reduced even further. In an embodiment of the invention, the dielectric 1110 need not be deposited, thereby leaving the conductor 810 as a suspended wire surrounded by air, an optimal dielectric having a dielectric constant of 1.

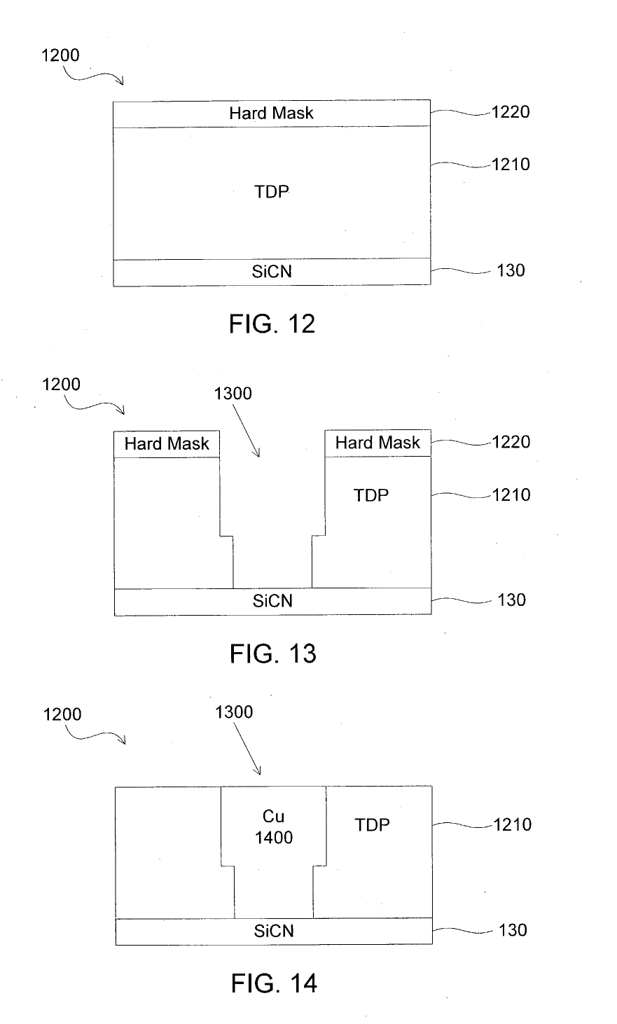

FIG. 12 is a partial cross section of a dual damascene IC 1200 illustrating a first stage of forming the dual damascene IC 1200. In the first stage, a thermal decomposable polymer (TDP) layer 1210 is deposited (via PVD, CVD, spin on etc.) on a bottom barrier layer 130 via PVD, CVD, spin on or other techniques. In an alternative embodiment of the invention, a photoresist layer may be used in place of or on top of the TDP layer 1210. The TDP layer 1210 generally has a thickness equal to the desired thickness of a conductor to be used in the IC 1200. Optionally, like other layers, a hard mask 1220 may be deposited on the TDP layer 1210.

FIG. 13 is a partial cross section of the dual damascene IC 1200 illustrating a second stage of forming the dual damascene IC 1200. The second stage includes trench patterning of a trench 1300 within the TDP layer 1210 and hard mask 1220 via photolithography techniques, etching techniques and/or other techniques. The dual damascene structure 1300 is a via and metal trench combined structure with a metal width of about 30 nm to about 100 μm. Generally, the widths of the trench 1300 should be equal to the widths of the conductor to be used in the IC 1200. It will be appreciated by one of ordinary skill in the art that additional trenches 1300 can be formed in the IC 1200 if it is to have additional conductors. A photoresist layer (not shown) can then be removed via ash and clean techniques.

FIG. 14 is a partial cross section of the dual damascene IC 1200 illustrating a third stage of forming the dual damascene IC 1200. Copper or other conductor is deposited within the trench 1300, forming a conductor 1400, via PVD, CVD, electrochemical plating or other techniques. In order to ensure that the height of the conductor 1400 is about equal to the height of the TDP layer 1210 and to remove metal between conductors deposited on the TDP layer 1210, the IC 1200 undergoes chemical mechanical polishing (CMP) or other technique to remove any excess conductor. In an embodiment of the invention, the chemical mechanical polishing or other technique can also remove the hard mask 1220.

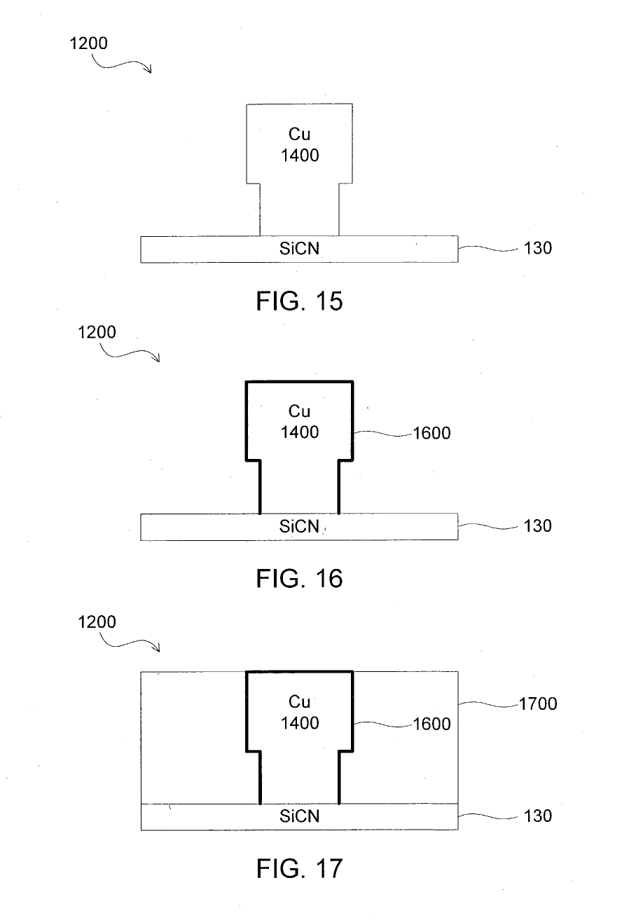

FIG. 15 is a partial cross section of the dual damascene IC 1200 illustrating a fourth stage of forming the dual damascene IC 1200. The TDP layer 1210 and optional hard mask 1220 (if made of TDP) is removed via thermal decomposition, leaving only the conductor 1400 standing as an island on the bottom barrier layer 130.

FIG. 16 is a partial cross section of the dual damascene IC 1200 illustrating a fifth stage of forming the dual damascene IC 1200. The conductor 1400 is selectively coated with a barrier material to cover the top and sides of the conductor 1400 to form a barrier 1600. As will be discussed further in conjunction with FIG. 18 and 19, the barrier 1600 can also encapsulate the bottom of the conductor 1400 in an embodiment of the invention. The barrier 1600 can be made of CoWP, CoWB, CoWB(p), or other materials and can be deposited substantially solely on the conductor 1400, e.g., using electrochemical plating (ECP), electroless plating or any selective deposit method. The barrier 1600 decreases coupling capacity over conventional capping barriers made of SiN or SiC. Further, the barrier 1600 improves the electron migration (EM) stress migration (SM) resistance (e.g., helps prevent migration of the conductor 1600).

FIG. 17 is a partial cross section of the dual damascene IC 1200 illustrating a sixth stage of forming the dual damascene IC 1200. A low k dielectric (insulator) 1700 is deposited onto the bottom barrier layer 130 surrounding the conductor 1400 using spin on or CVD. CMP is used to flatten the dielectric 1700. If there are voids between the conductor 1400 and a second conductor (not shown), then the capacitance between conductors is reduced. In an embodiment of the invention, the low k dielectric 1700 need not be deposited, leaving the conductor 1400 as a suspended wire with air as the dielectric material (having a dielectric constant of 1).

FIG. 18 is a partial cross section of a single damascene IC 1800 illustrating the single damascene IC 1800 having a recessed dielectric (SiCN) layer 130. In order to encapsulate at least a portion of the bottom of the conductor 810, the dielectric layer 130 is recessed before the selective application of the barrier coating 1010. The recessing of the dielectric layer 130 can be done via conventional wet and/or dry etch processes. It will be appreciated by one of ordinary skill in the art that the bottom metal 1810 must not be directly aligned with the conductor 810, else no bottom surface area of the conductor 810 will be exposed for application of the barrier coating 1010.

FIG. 19 is a partial cross section of a dual damascene IC 1900 illustrating the dual damascene IC 1900 having a recessed dielectric (SiCN) layer 130. In order to encapsulate at least a portion of the bottom of the conductor 1400, the dielectric layer 130 is recessed before the selective application of the barrier coating 1600. The recessing of the dielectric layer 130 can be done via conventional wet and/or dry etch processes. It will be appreciated by one of ordinary skill in the art that the bottom metal 1910 must not be directly aligned with the conductor 1400, else no bottom surface area of the conductor 1400 will be exposed for application of the barrier coating 1600.

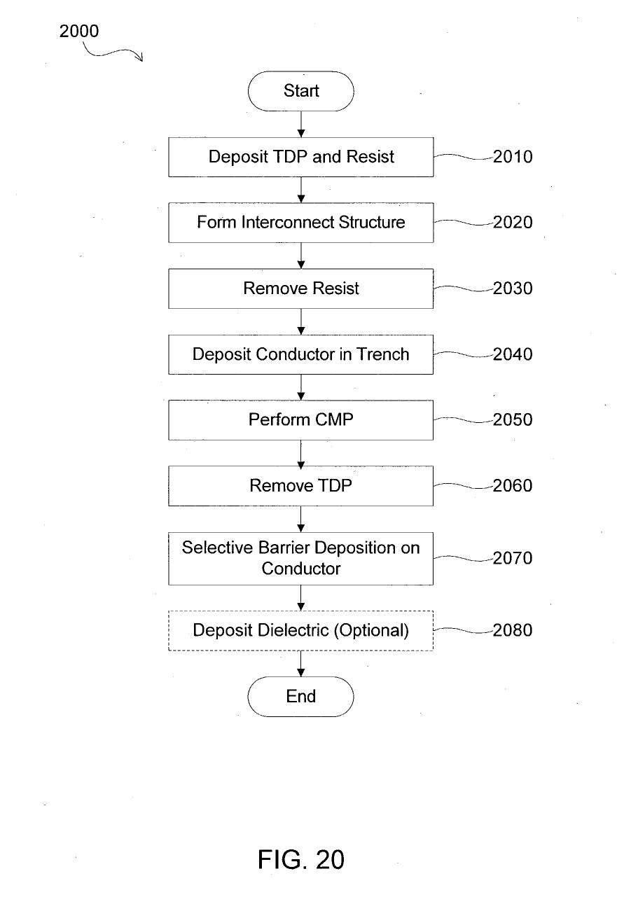

FIG. 20 is a flowchart illustrating a method 2000 of IC formation according to an embodiment of the invention. The method 2000 can be used for generating ICs having a single damascene structure, a dual damascene structure, a non-damascene structure or any other damascene structure. First, a TDP layer and a photoresist layer, such as a Poly Isoprene polymer, are deposited (via PVD, CVD, etc.) (2010) on top of a SiCN or other dielectric layer on a substrate. In another embodiment of the invention, only photoresist is used. In another embodiment of the invention, a hard mask can deposited on top of the TDP layer. The TDP layer generally has a thickness equal to the thickness desired for the conductor to be placed on the IC.

After the depositing (2010), an interconnect structure is formed (2020). The forming (2020) can include patterning a trench into the resist having dimensions substantially similar to the dimensions required for the conductor to placed on the substrate. For example, the trench can have a width of about 30 nm to about 100 μm. It will be appreciated by one of ordinary skill in the art that a plurality of trenches can be patterned in the resist in order to place multiple conductors on the IC.

The forming (2020) can also include etching a trench in the TDP layer. The trench is directly aligned with the trench formed by the patterning and can share the same dimensions as the trench formed by the patterning. Next, the resist is removed (2030).

A conductive material, such as copper, is then deposited (2040) in the trench in the TDP layer. CMP or other techniques may be used to remove (2050) any excess conductor deposited (2040). The CMP also removes (2050) the hard mask, if any. The TDP is then removed (2060) by applying heat to the TDP so that it decomposes. If the hard mask is made of a TDP material, then the heat also removes the hard mask. After removing (2060) the TDP, a conductor island remains standing on the IC on a dielectric layer, such as SiCN or other dielectric. The exposed sides of the conductor are then selectively coated (2070) with a barrier material, such as CoWB CoWP, and/or CoWB(p) using electrochemical plating (ECP), electroless plating or any selective method. The barrier material can have a thickness of about 2 nm to about 200 nm. In an embodiment of the invention, the dielectric layer can be recessed before the selective coating (2070) using dry and/or wet etching techniques so as to expose at least a portion of the bottom surface of conductor. Accordingly, the coating (2070) will coat the exposed bottom portion of the conductor with the barrier material in addition to the top and side surfaces. After the coating (2070), a dielectric is optionally deposited (2080) around the conductor's barrier and the IC can be completed via conventional techniques. Alternatively, the dielectric need not be deposited (2080) thereby leaving a suspended wire conductor surrounded by air, which is an optimal dielectric having a dielectric constant of 1. The method 2000 then ends.

The foregoing description of the illustrated embodiments of the present invention is by way of example only, and other variations and modifications of the above-described embodiments and methods are possible in light of the foregoing teaching. The embodiments described herein are not intended to be exhaustive or limiting. The present invention is limited only by the following claims.

1. A method, comprising:
forming a trench in a layer of dielectric material on a substrate;
depositing a first material into the trench;
depositing a second material into the trench; and
applying energy to the first and second materials to cause them to expand and form a dielectric barrier along at least a portion of the sides and bottom of the trench.

2. The method of claim 1, wherein the applying includes thermal annealing.

3. The method of claim 1, wherein the applying includes applying a laser to the first and second materials.

4. The method of claim 1, wherein the applying includes applying an electron beam to the first and second materials.

5. The method of claim 1, wherein the applying includes applying a microwave to the first and second materials.

6. The method of claim 1, wherein the applying includes applying ultraviolet light to the first and second materials.

7. The method of claim 1, wherein the first material includes platinum.

8. The method of claim 1, wherein the second material includes palladium.

9. The method of claim 1, further comprising depositing silicon into the trench.

10. A substantially impermeable barrier comprising at least two different materials in a trench of a layer of dielectric material that is formed by the method of claim 1.

11. An integrated circuit, comprising:
a substrate;
a dielectric layer disposed on the substrate and having a trench disposed therein;
a conductor disposed within the trench; and
a substantially impermeable barrier, including at least two different materials bonded together and expanded, located between the conductor and the dielectric layer.

12. The integrated circuit of claim 11, wherein one of the materials includes palladium.

13. The integrated circuit of claim 11, wherein one of the materials includes platinum.

14. The integrated circuit of claim 11, wherein the barrier further includes silicon.

15. The integrated circuit of claim 11, wherein the conductor includes copper.

16. The integrated circuit of claim 11, wherein the barrier has a thickness between about 2 nm to about 200 nm.

17. A method, comprising:
forming a conductor island on a substrate; and
encapsulating at least side surfaces and a top surface of the conductor with a barrier material.

18. The method of claim 17, further comprising depositing an insulator on the substrate adjacent to at least a portion of the barrier material.

19. The method of claim 17, wherein the encapsulating uses electrochemical plating.

20. The method of claim 17, wherein the encapsulating uses electroless plating.

21. The method of claim 17, wherein the encapsulating uses selective epitaxy.

22. The method of claim 17, wherein the barrier material includes CoWB.

23. The method of claim 17, wherein the barrier material includes CoWP.

24. The method of claim 17, wherein the barrier material includes CoWB(p).

25. The method of claim 17, wherein the barrier has a thickness between about 2 nm to about 200 nm.

26. The method of claim 17, wherein the conductor includes copper.

27. The method of claim 17, wherein the forming comprises:
depositing a layer of thermal decomposable polymer on a substrate;
forming a trench within the thermal decomposable polymer layer;
depositing a conductor within trench; and
thermally decomposing the thermal decomposable polymer.

28. The method of claim 17, further comprising:
recessing a dielectric between the substrate and the conductor island; and wherein the encapsulating also encapsulates at least a portion of the bottom of the conductor island.

29. An integrated circuit having a conductor encapsulated with a substantially impermeable barrier along the conductor's top and side surfaces made according to the method of claim 17.

30. An integrated circuit, comprising:
a conductor disposed on a substrate; and
a substantially impermeable barrier encapsulating at least a top surface and side surfaces of the conductor.

31. The integrated circuit of claim 30, further comprising an insulator adjacent to at least a portion of the barrier.

32. The integrated circuit of claim 30, wherein the barrier includes CoWB.

33. The integrated circuit of claim 30, wherein the barrier includes CoWP.

34. The integrated circuit of claim 30, wherein the barrier includes CoWB(p).

35. The integrated circuit of claim 30, wherein the barrier has a thickness between about 2 nm to about 200 nm.

36. The integrated circuit of claim 30, wherein the conductor includes copper.

37. The integrated circuit of claim 30, wherein the substantially impermeable barrier also encapsulates at least a portion of a bottom surface of the conductor.
